(19) United States
(12) Patent Application Publication
(10) Pub. No.: US 2024/0125816 A1
(43) Pub. Date: Apr. 18, 2024

(54) Probe Head

(71) Applicant: PMK Mess- und Kommunikationstechnik, GmbH, Bad Soden am Taunus (DE)

(72) Inventors: Michael J Mende, Portland, OR (US); Mark Heimann, Bad Soden am Taunus (DE); Richard Booman, Lake Oswego, OR (US); Philipp Palffy-Daun-Seiler, Bad Soden am Taunus (DE); Michael Engels, Krefeld (DE); Nadja Laeaeperi, Koenigstein im Taunus (DE); Benno Jacobs, Duisburg (DE); Michael D Stevens, Hillsboro, OR (US); Nicolas Frabasile, Hattersheim am Main (DE); Peter Hildenhagen, Alpen (DE); Kai Klein, Neu-Anspach (DE); Jurij Weber, Schwalbach am Taunus (DE); Iris Zimmermann, Mainz (DE); Juergen Trueller, Gernheim (DE); Thomas Podrebersek, Rheurdt (DE); Michael Eube, Xanten (DE); Frank Pannes, Duisburg (DE); Matthew M Mende, Portland, OR (US)

(21) Appl. No.: 18/486,156

(22) Filed: Oct. 13, 2023

Related U.S. Application Data
(60) Provisional application No. 63/415,972, filed on Oct. 13, 2022.

(51) Int. Cl. G01R 1/067

(52) U.S. Cl. CPC G01R 1/06766

(57) ABSTRACT

A probe head with a cylindrical portion and an oblique truncated portion angled downward toward a high-powered electronic device under testing. The probe head has a proximal end comprising an oblique truncated cone portion angled relative to the longitudinal axis at an input angle and has an analog signal input. The probe head has a digital signal output provided on the distal end of the housing.

### CROSS REFERENCE TO RELATED APPLICATION

This application claims the benefit of U.S. provisional application No. 63/415,972, filed Oct. 13, 2022, and entitled the same. The contents therein are hereby incorporated by reference.

### FIELD OF THE DISCLOSURE

The present disclosure relates to probe heads and their related assemblies and stands used in high-performance electronic device testing.

### BACKGROUND OF THE DISCLOSURE

Electronic probing devices such as probe heads are used in a wide range of test and measurement applications, such as performing dielectric, pulse, bias-stress, or voltage withstand tests on circuit boards. Probe heads usually convert an analog input signal to a digital output signal for further processing. Probe tips are typically attached to dedicated test points of a test specimen, a device under testing, (“DUT”), such as a printed circuit board.

Electronics probing devices and coils and applications are necessary in the engineering, development, manufacturing, quality control, repair, and maintenance of devices having advanced semiconductors. High-performance electronics have sensitive circuitry and control technology because these electronics have high energy densities that need to be managed efficiently and correctly to prevent malfunctions and electric fires. Accordingly, it is a standard industry practice in the art that every electronic device circuitry, board, and control unit has dedicated electrically conductive test interfaces or spots. The location and orientation of these test spots vary depending on the device. For example, test spots are probed to “listen” to the frequency that is applied during operation or during any operation state, and the signal is measured to ensure the electronic device circuitry, board, or control unit correctly manages the energy loads.

Electronics testing devices tend to fail to keep up with the needs of electronics and semiconductor innovators. In one example, semiconductor manufacturers that produce advanced semiconductors such as those containing GaN or SiC would need high-performance probes for characterization, quality assurance, and research and development. In another example, solar and wind power companies would need high-performance probes for the development and testing of inverters, transmitters, and other power electronics that convert renewable energy to electricity. Defense contractors and aerospace companies also need high-performance probes for the testing and development of avionics, communications, radar, or any other high-frequency systems.

Reaching a wide range of test points on a DUT with one probe head and being able to have multiple probes connecting to one DUT without suffering from signal quality losses are some of the key performance indicators in designing probe heads. However, traditional testing devices suffer decreases in signal quality when more than one dedicated test point on a DUT is simultaneously probed.

Established probe heads are not without significant drawbacks. For example, employing hand-held probe heads can be arduous and time-consuming. In hazardous environments with high voltages, employing hand-held probes may not be feasible. Traditional probing devices also are not suitable for tests having extended durations due to overheating.

Since hand-held probing devices generally require more space, the number of hand-held probe heads in a confined space is limited, making it difficult or impossible to use multiple traditional probing devices on dense electronic assemblies. Attempts have been made in the industry to reduce the amount of space a probing device requires in the proximity of the DUT. Reaching into tight spaces by mounting traditional probing devices on stands or moving the traditional device further away from the test point requires the tip cable to be longer and bend at a 90-degree angle. When a probe tip is attached to or contacts the test point on the DUT, bending stresses from the bent input cable might be inflicted on the DUT via the probe tip. This can lead to damages on the DUT and can reduce the stability of the deployed Probe head. In addition, electrical performance and signal fidelity typically degrade with increasing input cable length.

Traditional probing devices also have limitations regarding bandwidth and common mode rejection ratios in high-frequency, high-power, and high-voltage scenarios. For example, traditional probing devices have difficulty measuring small signals accurately when the small signals are overshadowed by larger common mode voltages. In particular, the DUT is a power electronic device for high voltage switches. In another example, traditional probing devices have difficulty accurately measuring very fast changing signals that are typical in radio frequency applications and in high-speed digital circuits.

Accordingly, there remains room for substantial improvement.

### SUMMARY OF THE DISCLOSURE

What is needed is a probe head requiring shorter input cables to obtain measurements with greater signal fidelity and reduced physical stress on measurement test points. The probe head accurately resolves high bandwidth, can measure small differential signals in the presence of large common mode voltages, and can operate over a wide temperature range for extended durations.

In one embodiment, the probe head comprises a housing having a first housing portion and a second housing portion joined along a longitudinal axis wherein the housing has a cylindrical portion at a distal end and has a proximal end that tapers into an oblique truncated portion having an input angle. The probe head also has a truncated end surface of the oblique truncated portion with an input opening oriented perpendicularly to an input axis.

In another embodiment, the probe head comprises a housing having a longitudinal axis, a proximal end, and a distal end. The proximal end comprises an oblique truncated cone portion angled relative to the longitudinal axis at an input angle and an analog signal input. A digital signal output is provided on the distal end of the housing.

In some embodiments, the probe head has a mount to receive an external support structure. The probe head is positioned so the probe tip is in contact with a test point on a device under testing (DUT), and the test point, the probe tip, and the input cable are aligned with the probe head proximal end along the input axis.

### BRIEF DESCRIPTION OF THE DRAWINGS

The accompanying drawings illustrate several embodiments of the disclosure. Together with the description, the drawings serve to explain the principles of the disclosure.

FIG. 1 shows a left side view of an exemplary probe head.

FIG. 2 shows a left front perspective view of an exemplary probe head.

FIG. 3 shows a right rear perspective view of an exemplary probe head.

FIG. 4A shows a right side view of an exemplary probe head with a power source compartment lock in a screw knob configuration.

FIG. 4B shows a right side exploded view of an exemplary probe head.

FIG. 5 shows a left side interior view of an exemplary probe head assembly.

FIG. 6 shows a schematic of interchangeable power source options.

FIG. 7 shows a left side view of an exemplary probe head assembly with stand.

FIG. 8 shows a left side view of an alternative embodiment of an exemplary probe head assembly with stand.

### REFERENCE NUMERALS OF THE DRAWINGS

1 Probe head
2 Electrically isolating layer
3 Housing
5 Proximal end
7 Distal end
8 Distal end surface
9 Longitudinal axis
11 Cylindrical portion
12 Top side of the cylindrical portion
13 Oblique truncated portion
14 Bottom side of the cylindrical portion
15 Input axis
17 Input angle
18 Truncated end surface
19 Input opening
21 Output portion
23 Output axis
25 Output opening
27 Output angle
28 Output end surface
29 Probe head mount
31 Mounting axis
33 First housing portion
35 Second housing portion
37 Tip connector
39 Power source compartment
41 Power source compartment opening
43 Power source compartment lock
45 Power source compartment screw knob
47 Thread
49 Battery
51 Probe head assembly
53 Signal input assembly
55 Signal output assembly
57 Input cable
59 Probe tip
61 Device Under Testing (DUT)
63 Fiber optic cable
65 Bend limiter
66 Interior space
67 Circuit board
69 Analog-to-digital signal transmitter
71 Male connector plug
73 Isolated power adapter
75 Power-over-fiber adapter
77 Probe head stand
79 Monopod stand mount portion
81 Monopod leg portion
83 Monopod foot portion
85 monopod tiltable joint connection
87 Upper leg
89 Lower leg
91 Forward-facing toe portion
93 Backward-facing toe portion
95 Bipod stand mount portion
96 Test point
97 Left bipod leg
98 DUT structural component
99 Right bipod leg
101 Bipod tiltable joint connection

### DETAILED DESCRIPTION

The present disclosure generally provides for probe heads and their related assemblies and stands used in electronics testing applications for high frequency, high bandwidth measurements. Probe heads of the disclosure provide for shorter tip cables to be used, resulting in higher signal fidelity measurements and reduced stress placed on measurement test points on a DUT or test board, especially when test points are difficult to access. One objective is to provide a probe head that is versatilely applicable in a wide range of DUT test points in an ergonomic manner while accurately resolving small differential signals at high bandwidths. It is also an objective to provide a probe head that can be connected to the DUT in a small, confined area, such that the probe head density per DUT can be increased, so more than one test point on a DUT can be simultaneously probed. A method for operating a probe head is provided, comprising the steps of mounting a bipod to a housing of the probe head, mounting an input tip to the probe head housing, and using a probe head tip as a third leg to stabilize the probe head.

The probe head is suitable for signal transmission in a test and measurement application. Signal transmission may be analog, digital, or analog to digital signal transmission. Signal transmission may comprise an analog input signal and a digital output signal. The analog input signal may be a high-frequency signal such as a radio frequency signal. The digital output signal may be an optical signal.

In the following sections, detailed descriptions of examples and methods of the disclosure will be given. The description of both preferred and alternative examples is exemplary only, and it is understood that to those skilled in the art that variations, modifications, and alterations may be apparent. It is therefore to be understood that the examples do not limit the broadness of the aspects of the underlying disclosure as defined by the claims.

### DETAILED DESCRIPTIONS OF THE DRAWINGS

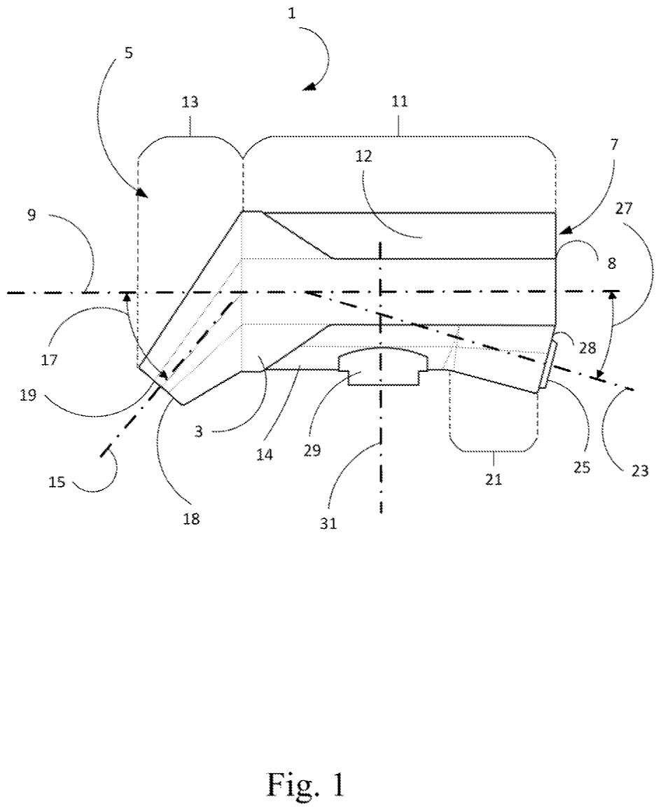

Referring now to FIG. 1, a left side view of an exemplary probe head is shown. The probe head 1 may comprise a housing 3 with a proximal end 5 and a distal end 7. The housing 3 may be configured such that an analog signal input is received though a housing proximal end, and a digital signal output exits through a housing distal end. The proximal end 5 may be the housing end facing the analog signal input. The distal end 7 may be the housing end facing the digital signal output. The housing 3 may comprise a cylindrical portion 11 extending along a longitudinal axis 9. The cylindrical portion 11 may extend from the distal end 7 towards an oblique truncated portion at the proximal end. The cylindrical portion 11 may comprise a top side 12 and a bottom side 14. The cylindrical portion 11 may comprise a substantially parallel cylindrical surface which may comprise protruding elements for haptic, design, or technical reasons. The housing 3 may comprise an input opening 19, preferably on its proximal end. The input opening 19 may be configured as a port, hub or interface for signal input components such as analog signal lines, analog probe tips, analog probe tip connectors, or the like.

The housing 3 may be constructed of at least a metal layer or a solid layer with electrically isolating properties. Preferably, the housing 3 comprises a core layer of metal and a cladding layer having electrically isolating properties. For example, the core layer may be a metal such as brass, and the electrically isolating layer may be a rubber coating.

In preferred embodiments, the probe head is angled. On its proximal end 5, the housing 3 culminates into an oblique truncated portion 13. The oblique truncated portion 13 provides a port or an interface for the analog signal input. The oblique truncated portion 13 extends along an input axis 15 and inclines downward from the longitudinal axis 9 at an input angle 17. An inclination angle is the angle between the longitudinal axis 9 and the input axis 15, rotated downwards from the longitudinal axis 9 from a forward-facing perspective. The inclination angle can range from approximately 40 degrees to approximately 60 degrees. Preferred embodiments can have an inclination angle of 45 degrees, 50 degrees, 55 degrees, or 60 degrees.

The oblique truncated portion 13 may have a cone shape with a truncated end surface 18 at the proximal end of the housing. The truncated end surface 18 is perpendicular to the input axis 15. The input opening 19 at the truncated end surface 18 has a circular cross-section, but other embodiments may have input openings in other shapes such as polygonal or triangular. The input opening 19 is oriented perpendicularly to the input axis 15. Signal input apparatuses such as a signal line cable, probe tip, and their related adapters are attached to or threaded through the input opening 19. The input opening 19 is aligned to face the DUT head-on, which allows a connection with the DUT in a substantially straight line. With such a configuration, signal input line bending such as bending of a signal cable line is minimized when connected to a test point of a DUT. The electrical performance or signal quality is increased because the exemplary configuration provides an increase in probe tip contact pressure at the DUT test point. Further, stresses inflicted on the DUT test point by the probe tip are reduced due to the reduced bending momentum, making the probe head more stable.

In some embodiments, the housing 3 of the probe head narrows towards the input opening and widens towards the outlet portion. A plurality of probe heads can be used simultaneously to measure several test points of one DUT in a confined space.

The oblique truncated cone portion 13 may point in a downward-facing direction which is defined by the input angle 17 and the distance between a test spot on a DUT and the input opening is reduced. The configuration having the inclination angle allows the tip cable to be shorter, which allows for better signal fidelity and less stress on the DUT test point. Tip cables can have a length from approximately 1 cm to 10 cm with preferred examples being 2 cm, 3, cm, 4 cm, 5 cm, or 6 cm.

The oblique truncated cone portion 13 may merge with the cylindrical portion 11. The input opening 19 may be provided on the narrow end of the oblique truncated cone portion 13. This truncated end surface of the oblique truncated cone portion may be oriented perpendicular to the axis of the oblique truncated cone portion. Hence, in the example shown in FIG. 1, the axis of the oblique truncated cone portion is defined as the input axis. The oblique truncated cone portion can be configured such that it protrudes beyond the mantle surface of the first cylindrical portion.

On its distal end 7, the probe head housing 3 may comprise an output portion 21 with an output axis 23 and an output opening 25. The output portion 21 may be configured as a port, hub, or interface for digital signal outputs, in particular optical signal outputs. For example, the output portion may be configured such that an optical cable can extend from the inside of the housing 3 to the outside via the output opening 25. The output portion may comprise an output end surface 28, facing the distal end 7. The cylindrical portion 11 may comprise a distal end surface 8. The output portion 21 may protrude from the cylindrical portion 11 such that the output end surface 28 connects with the distal end surface 8 of the cylindrical portion 11.

The output axis 23 may be inclined downwards from the longitudinal axis 9 and towards the distal end 7 of the housing 3. The output portion 21 may be configured as a protrusion, protruding out of the mantle surface of the cylindrical portion 11 at the output angle 27. The base of the output portion 21 may merge with the distal end of the housing 3. The output opening 25 may be provided on the base of the output portion 21, facing towards the distal end 7 of the housing 3.

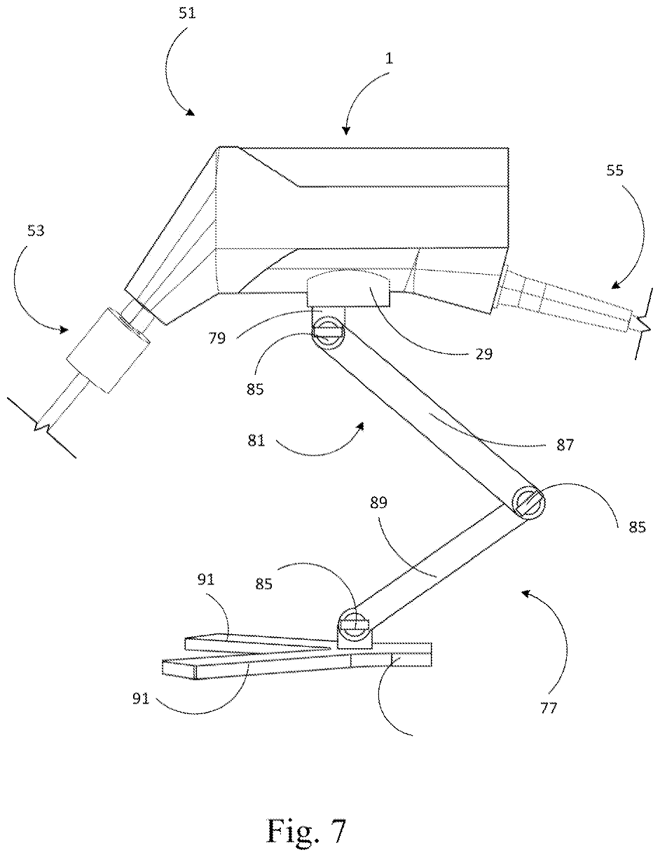

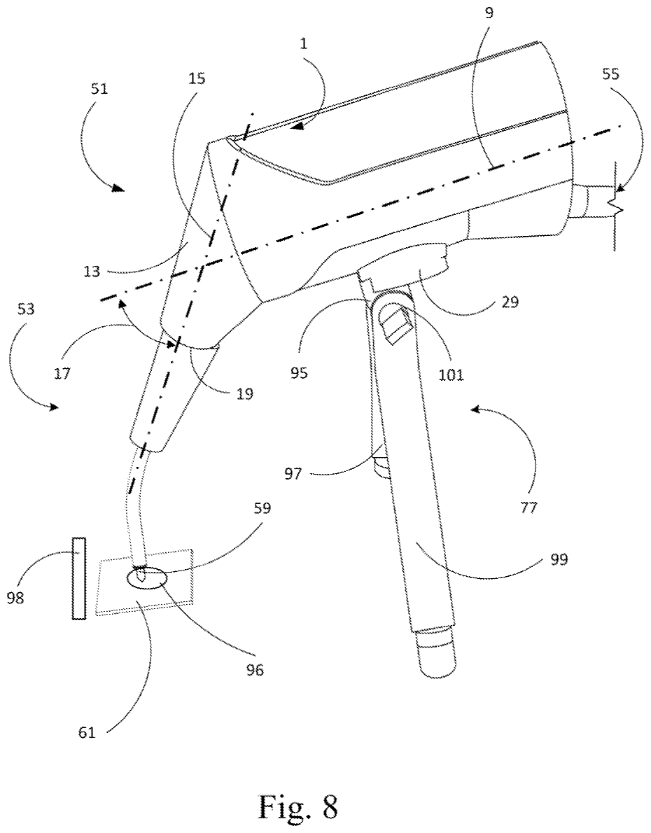

The probe head 1 may comprise a probe head mount 29, which may be provided on the cylindrical portion 11 of the housing 3. The probe head mount 29 may have a mounting axis 31. The probe head mount 29 may be configured to receive an external support structure such as a stand, a bipod, a monopod, an arm, a foot, or combinations thereof or as shown in FIGS. 7 and 8. In preferred embodiments, the probe head mount 29 is arranged substantially at the center of gravity of the probe head, providing optimal balance and stability. The probe head mount may face downward or in the same direction as the oblique truncated cone portion. In preferred embodiments, the probe head mount is located on a bottom side of the cylindrical housing 14 between the oblique truncated cone portion and the output portion.

The probe head 1 may be configured such that the longitudinal axis 9, the input axis 15, the output axis 23, and the mounting axis 31 all lie in one plane, which may be a vertical plane. The input axis 15, the output axis 23, and the mounting axis 31 may intersect the longitudinal axis 9 at different intersection locations. Alternatively, the input axis 15, the output axis, 23, and/or the mounting axis 31 may intersect the longitudinal axis 9 at a common location.

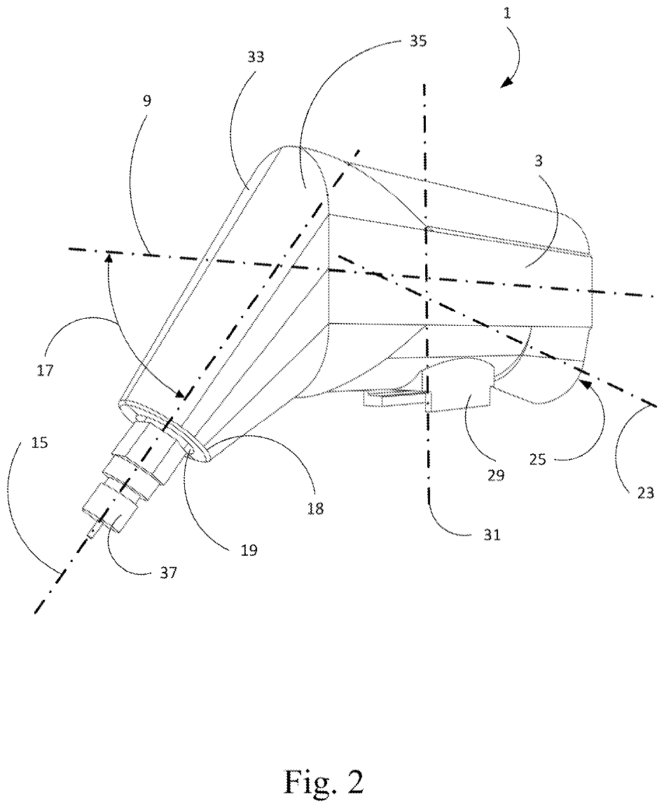

Referring now to FIG. 2, a left front perspective view of an exemplary probe head is shown. Exemplary embodiments may comprise a housing made of a single portion or a plurality of portions. The exemplary embodiment of FIG. 2 has a housing 3 of the probe head 1 which comprises a first housing portion 33 and a second housing portion 35 joined along a longitudinal axis. Nevertheless, alternative embodiments may comprise a housing having a first portion, a second portion, and a third portion, or other plurality of portions. The first housing portion 33 and the second housing portion 35 may be substantially symmetrical in a vertical plane. The vertical plane is defined by the longitudinal axis 9 and the input axis 15. Preferably, the vertical plane is defined by the longitudinal axis 9, the input axis 15, the output axis 23, and the mounting axis 31. A rubber coating may seal the second housing portion and the first housing portion to one another.

The probe head 1 is shown in combination with a tip connector 37 to which a signal input line may be attached. The tip connector 37 may be suitable for an analog signal input and may adhere to industry standards for analog signal adapters such as MMCX adapters.

The probe head mount 29 can have a rectangular cross section protruding downward from the housing 3 along the mounting axis 31. The probe head mount 29 may comprise a shoe mount. The shoe mount can be a hot or cold shoe mount.

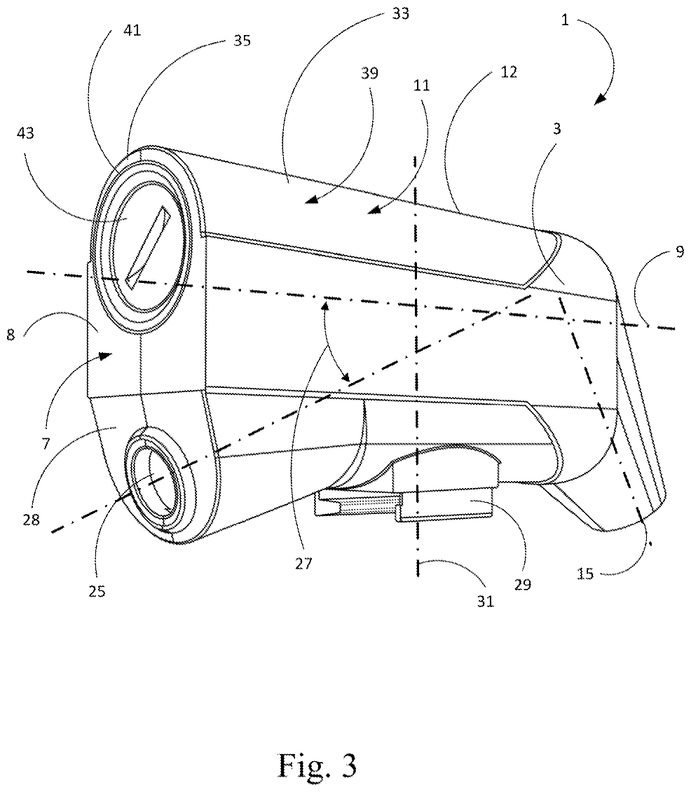

Referring now to FIG. 3, a right rear perspective view of an exemplary probe head is shown. The housing 3 of the probe head 1 may comprise a power source compartment 39. The power source compartment 39 may be provided on the inside of the housing 3. The power source compartment 39 may be provided along the cylindrical portion 11 of the housing 3. Preferably, the power source compartment 39 is provided along the top side 12 of the cylindrical portion 11 of the housing 3. The probe head 1 may comprise a power source compartment opening 41 and a power source compartment lock 42, suitable for opening and closing the power source compartment opening 41. Power source compartment opening 41 and lock 42 may be provided on the distal end 7 of the housing 3. The power source compartment lock 42 may be provided in a screw-head configuration, in which case the lock 42 is substantially embedded into the opening 41 to be either flush with the housing or recessed. The power source compartment lock 42 in the screw head configuration may comprise a slotted screw, Phillips screw head, an Allen screw head or the like.

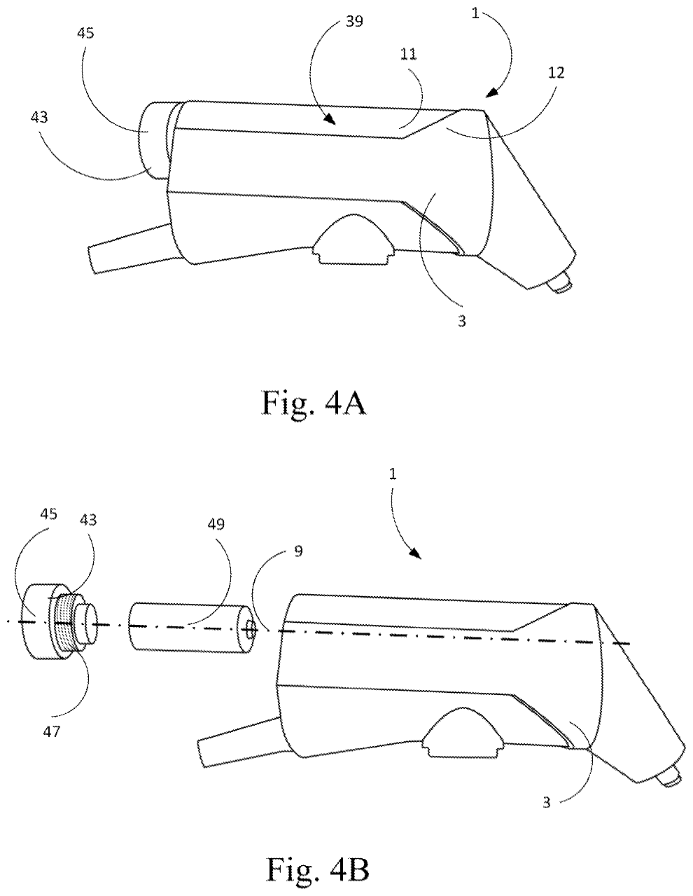

Referring now to FIG. 4A, a right side view of an exemplary probe head with a power source compartment lock in a screw knob configuration is shown. The power source compartment lock 43 may comprise a screw knob 45 suitable for manual assembly and disassembly of the power source compartment lock 43 into the power source compartment opening 41. The power source compartment screw knob 45 may be configured to allow toolless assembly and disassembly of the lock 43 and may protrude from the housing.

Referring now to FIG. 4B, a right side view an exploded view of an exemplary probe head is shown. The exploded view shows the probe head 1, the power source compartment lock 43, and a battery 49, exploded substantially along the longitudinal axis 9 of the probe head 1. The battery may be of type AA. The power source compartment lock 43 is shown in the screw knob configuration and may comprise a screw knob 45 and a thread 47, configured for threading with the power source compartment opening 41. In an assembled configuration, the battery 49 is inserted into the battery compartment 39, and the power source compartment 39 is sealed by manually operating the screw knob to fasten the power source compartment lock 43 into the opening 41.

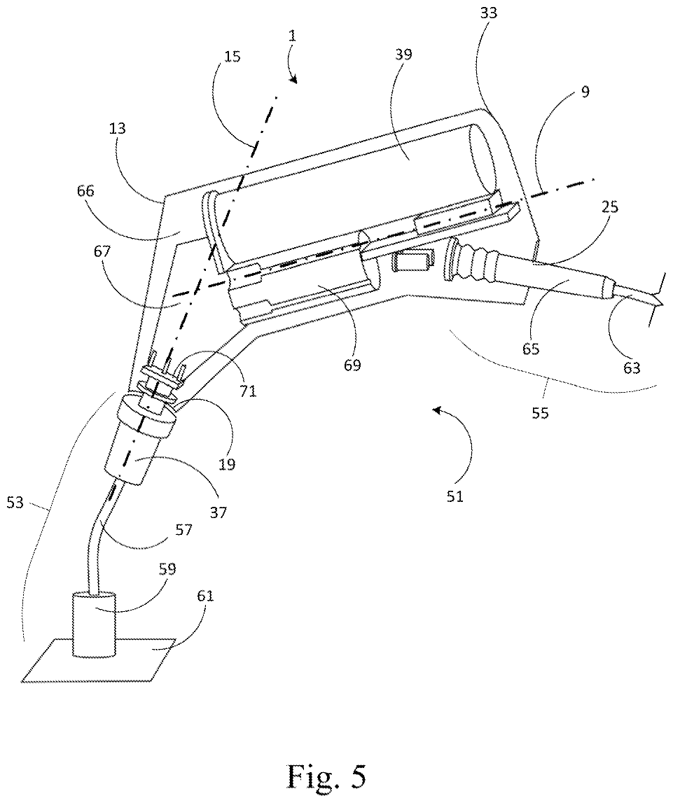

Referring now to FIG. 5, a left side interior view of an exemplary probe head assembly is shown. The exemplary probe head assembly 51 may comprise a probe head 1, a signal input assembly 53, and a signal output assembly 55. The signal input assembly 53 may be mounted to the probe head 1 via the input opening 19. The signal input assembly 53 may comprise a tip connector 37, an input cable 57, and a probe tip 59. The signal input assembly 53 may comprise components suitable and optimized for efficient analog signal retrieval from a DUT 61. Input cable 57 and/or input connector may be an analog signal transmitter which adheres to or is compatible with signal input connector standards like MMCX, MCX, or the like. The tip connector 37 may comprise a fastener such as a releasable screw or a thumbwheel. The signal output assembly 55 may comprise a fiber optic cable 63 for digital signal output and a bend limiter 65.

The probe head 1 is shown only with the first housing portion 33, the second housing portion 35 being removed to reveal an interior space 66. The probe head 1 may comprise a circuit board 67 for analog signal processing, a male connector plug 71 connected to the circuit board, the power source compartment 39, and an analog-to-digital signal transmitter 69 for analog to digital signal conversion in the interior space. In preferred embodiments, the circuit board extends from the cylindrical portion of the probe head to the oblique truncated portion. The circuit board may have an irregular polygonal shape such as an irregular trapezoid to conform to the interior space of the oblique truncated portion that tapers toward the proximal end of the probe head.

During operation of the probe head assembly 51, the probe tip 59 contacts the DUT 61 and retrieves analog signals. Those signals are transmitted to the probe head 1 via the analog input cable 57 and the tip connector 37. Inside the probe head 1, the analog signals are retrieved via the male connector plug 71 and transmitted to circuit board 67 for analog signal processing. Subsequently, the analog-to-digital signal transmitter 69 converts the processed analog signals to a digital signal using power retrieved from the power source compartment 39. The analog-to-digital signal transmitter 69 may be an analog to optical analog-to-digital signal transmitter. The digital signal may be output or produced via the signal output assembly. Specifically, the analog-to-digital signal transmitter 69 injects the digital signal into the fiber optic cable 63, which guides the digital signal to external digital signal post-processing apparatuses. The probe head 1 may comprise digital signal processing apparatuses configured to process the digital signal before it leaves the probe head 1 via the fiber optic cable 63. The probe head 1 may comprise a transmitter chamber receiving the analog-to-digital signal transmitter. The probe head 1 may comprise a temperature control device configured to keep the signal transmitter at a constant predetermined temperature.

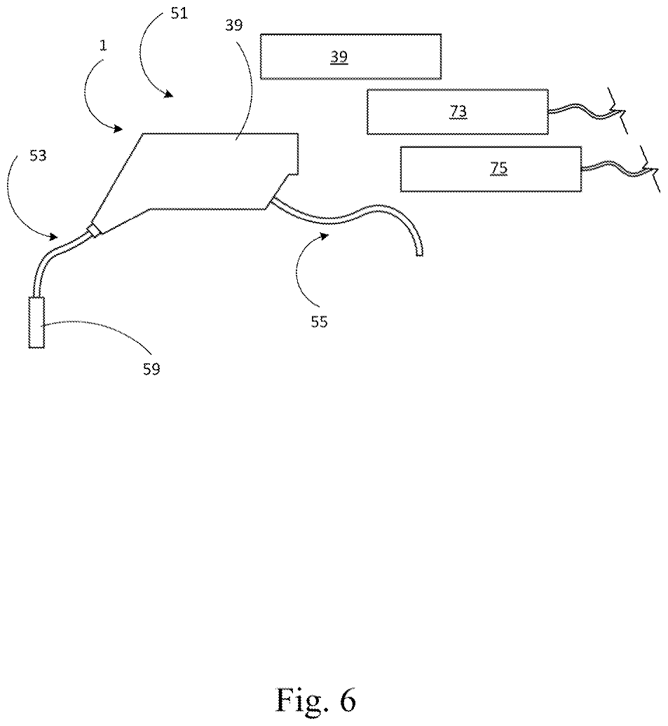

Referring now to FIG. 6, a schematic of interchangeable power source options is shown. The schematic shows a probe head assembly 51, comprising the probe head 1, the signal input assembly 53, and the signal output assembly 55. The power source compartment 39 may have a modular configuration, allowing to use at least one of a battery 49, an isolated power adapter 73, and/or a power-over-fiber adapter 75 as power source.

The power source compartment 39 may be configured to receive either one of the batteries 49, the isolated power adapter 73, or the power-over-fiber adapter 75 inside probe head 1. In a first configuration, an AA or 18650 type battery is inserted into the power source compartment 39. In a second configuration, the isolated power adapter 73 is inserted into the power source compartment 39. In a third configuration, the power-over-fiber adapter 75 is inserted into the power source compartment 39.

In the first configuration, the probe head 1 may be powered only by the battery. This allows omission of an additional electrical connection and operating the probe head 1 without a power-over-fiber cable. Being able to operate without power-over-fiber broadens the spectrum of possible use cases for the probe head 1. The omission of an additional electrical cable for powering the probe head 1 simplifies use of the probe head 1, increases operational safety and avoids electromagnetic fields created by electricity flowing through such a wire.

In the second configuration, the probe head may be powered only by the isolated power adapter. This also allows operating the probe head 1 without a power-over-fiber cable. Operating the probe head 1 in the isolated power adapter configuration is therefore possible wherever a suitable power supply is available.

In the third configuration, the probe head 1 may be powered only by the power-over-fiber cable. Such adapters may comprise a sensor to provide intelligent data that can be read and analyzed to monitor and adjust the power level required by the probe head. Operating the probe head via power-over-fiber allows the probe head to be remotely powered via the optical cable, while providing electrical isolation between the device and the power supply. In this configuration, the probe head can be protected from dangerous voltages and can be used in environments where it is important to avoid the electromagnetic fields or the presence of electrical cables.

Referring now to FIG. 7, a left side view of an exemplary probe head assembly with stand is shown. The probe head assembly 51 is shown as a combination of the probe head 1, the signal input assembly 53, the signal output assembly 55, and the probe head stand 77. The probe head stand 77 may be connected to the probe head mount 29 of the probe head 1, which may be a shoe mount. The probe head stand 77 may be releasably attached to the probe head 1. The probe head stand 77 may be provided in a monopod configuration. In the monopod configuration, the probe head stand 77 comprises a monopod stand mount portion 79, a monopod leg portion 81, and a monopod foot portion 83. The probe head stand 77 may be mounted to the probe head mount 29 via the monopod stand mount portion 79. The monopod stand mount portion 79 may be connected to the monopod leg portion 81 via a monopod tiltable joint connection 85. The monopod leg portion may comprise an upper leg 87 and lower leg 89. The upper leg 87 and the lower leg 89 may be connected via the monopod tiltable joint connection 85 in a heel-type joint. The monopod foot portion 83 may comprise two forward-facing toe portions 91 arranged in a V-shaped configuration and one backward-facing toe portion 93.

Referring to FIG. 8, a left side view of an alternative embodiment of an exemplary probe head assembly with stand is shown. This particular embodiment shows the probe tip contacting a test point 96 on the DUT where the test point is in a confined, hard-to-reach location due to the presence of a DUT structural component 98 or any other obstruction, obfuscation, or extended surface of a DUT such as walls, housings, brackets, fasteners, heat sinks, cooling fins, cables, or other probing devices. Rather than wrapping, bending, or reaching around structural components, the input cable is substantially straight and within the natural bend radius tolerances of the input cable material. The test point and probe tip are aligned with the probe head proximal end rather than the probe head proximal end being placed further away from the test point. The input cable is relatively short, having a length from approximately 3 cm to approximately 6 cm.

The probe head assembly 51 is shown as a combination of the probe head 1, the signal input assembly 53, the signal output assembly 55, and the probe head stand 77. The probe head stand 77 may be connected to the probe head mount 29 of the probe head 1, which may be a shoe mount. The probe head stand 77 may be releasably attached to the probe head 1. The probe head stand 77 may be provided in a bipod configuration. The probe head stand 77 in the bipod configuration may comprise a left bipod leg 97, a right bipod leg 99 and a bipod stand mount portion 95. The probe head stand 77 in the bipod configuration may be mounted to the probe head 1 mount via the bipod stand mount portion 95. The bipod stand mount portion 95 may be connected to left bipod leg 97 and the right bipod leg 99 via a bipod tiltable joint connection 101. The left bipod leg 97 and the right bipod leg 99 may be rigidly connected to one another or made of one piece.

The probe head 1 may be configured such that the input tip 59 of the signal input assembly 53 may act as a third leg to stabilize the probe head assembly 51. In a state when the input tip 59 touches a DUT 61, the probe head assembly 51 may rest on the left bipod leg 97, the right bipod leg 99, and the input tip contacting the test board. In this configuration, three points are established, providing a secure positioning of the probe head assembly 51 during operation.

The input opening 19 of the probe head may face down towards the DUT 61. This can be the case, when the oblique truncated portion 13 of the housing is facing down at an inclination angle of about 50 degrees and when the input opening 19 is provided on the oblique truncated portion 13 of the housing 3. Vertical forces needed to arrest the forward leaning probe head in position, can be distributed from the DUT 16 via the probe tip 59 and other parts of the signal input assembly to the probe head.

### CONCLUSION

Although the disclosure has been described in terms of exemplary embodiments, the disclosure is not limited thereto. This description of the exemplary embodiments is set to be understood in connection with the figures of the accompanying drawings, which are to be considered part of the entire written description. Relative terms such as “lower,” “upper,” “horizontal,” “vertical,” “above,” “below,” “up,” “down,” “top,” “bottom,” “back,” and “front” as well as derivatives such as “horizontally,” “downwardly,” and “upwardly,” should be construed to refer to the orientation as then described or as shown in the particular figure under discussion. These relative terms are for convenience of description and do not require that the probe head be constructed or operated in a particular orientation. Terms concerning attachments and coupling such as “connected” refer to a relationship wherein structures are secured or attached to one another either directly or indirectly through intervening structures, as well as both movable or rigid attachments or relationships, unless expressly described otherwise.

While this specification contains many specific implementation details, these details should not be construed as limitations on the scope of any disclosures or of what may be claimed. It should be understood that these exemplary embodiments may be susceptible to various modifications and may present in alternative forms. All statements herein reciting principles, aspects, and embodiments of the disclosure are intended to encompass both the structural and the functional equivalents thereof. Additionally, it is intended that such equivalents include both currently known equivalents and any elements developed in the future that perform the same function regardless of structure. The claims are not intended to be limited to the particular embodiments, modifications, and alternative forms disclosed but are intended to cover all modifications, equivalents, and alternatives falling within the spirit and scope of the disclosure.

What is claimed is:

1. A probe head comprising:
a housing having a first housing portion and a second housing portion joined along a longitudinal axis,
wherein the housing has a cylindrical portion at a distal end and has a proximal end that tapers into an oblique truncated portion having an input angle; and
a truncated end surface of the oblique truncated portion with an input opening oriented perpendicularly to an input axis.

2. The probe head of claim 1, further comprising a probe head mount configured to receive an external support structure, wherein the probe head mount is provided on a bottom side of the cylindrical housing and has a mounting axis.

3. The probe head of claim 2, wherein the external support structure is a bipod or a monopod.

4. The probe head of claim 1, further comprising a tip connector mounted to the probe head at the input opening.

5. The probe head of claim 4, further comprising an input cable connected to the tip connector.

6. The probe head of claim 5, further comprising a probe tip connected to the input cable along the input axis.

7. The probe head of claim 6, wherein the probe tip is in contact with a test point on a device under testing (DUT), and the test point, the probe tip, and the input cable are aligned with the probe head proximal end along the input axis.

8. The probe head of claim 7 wherein the test point is obfuscated by a DUT structural component.

9. The probe head of claim 7, wherein the input cable is substantially straight.

10. The probe head of claim 7, wherein the input cable has a length from about 3 cm to about 6 cm.

11. The probe head of claim 8 wherein the input cable is substantially straight.

12. The probe head of claim 8 wherein the input cable has a length from about 3 cm to about 6 cm.

13. The probe head of claim 1 further comprising a signal output assembly having a fiber optic cable for digital signal output.

14. The probe head of claim 1, further comprising a modular power source compartment.

15. A probe head comprising a housing having a longitudinal axis, a proximal end, and a distal end,
wherein the proximal end comprises
an oblique truncated cone portion angled relative to the longitudinal axis at an input angle,
an analog signal input provided on the oblique truncated cone portion, and
a digital signal output provided on the distal end of the housing.

16. The probe head according to claim 15,
wherein the truncated cone portion is tapered towards the proximal end and along its input axis such that a truncated end surface is provided on the proximal end of the housing, and
wherein the analog signal input is provided on the truncated end surface.

17. The probe head according to claim 15, wherein the truncated end surface is perpendicular to the to the input axis.

18. The probe head according to claim 17,
wherein the housing comprises a cylindrical portion extending along the longitudinal axis and between the distal end and the oblique truncated cone portion, and
wherein the truncated cone portion extends beyond the cylindrical portion in the direction of the input axis.

19. The probe head according to claim 18, wherein the angle between the longitudinal axis and the input axis is from about 40 degrees to about 60 degrees.

20. The probe head according to claim 15, wherein the cylindrical portion comprises an output portion,
wherein the output portion protrudes from the cylindrical portion along an output axis at an output angle,
wherein the output angle is angled relative to the longitudinal axis, and
wherein the output angle is configured such that the output portion protrudes toward the distal end.

21. The probe head according to claim 20, wherein the output portion comprises an output end surface which is perpendicular to the output axis, and
wherein the digital signal output is provided on the output end surface.

22. The probe head according to claim 21, wherein the output portion is protruded such that the output end surface connects with a distal end surface of the cylindrical portion.

23. The probe head according to claim 20,
wherein the probe head further comprises a probe head mount having a mounting axis, and wherein the probe head mount is arranged on the cylinder portion.

24. The probe head according to claim 23, wherein the probe head mount is arranged on the cylindrical portion at a radial direction that is identical to the radial direction component of the input axis.

25. The probe head according to claim 23, wherein the probe head is configured such that the longitudinal axis, the input axis, the output axis, and the mounting axis all lie within one plane.

26. The probe head according to claim 15, wherein the housing comprises a first housing component and a second housing component.

27. The probe head according to claim 26, wherein the first and second housing components are split along a plane running along the longitudinal axis.

28. The probe head according to claim 27, wherein the first and second housing portions are configured such that they are symmetrical with respect to a vertical plane running along the longitudinal axis.
